(19) United States
(12) Patent Application Publication
(10) Pub. No.: US 2020/0132894 A1
(43) Pub. Date: Apr. 30, 2020

(54) SUPPORT FOR REFLECTIVE OPTICAL ELEMENT

(71) Applicant: CORNING INCORPORATED, Corning, NY (US)

(72) Inventors: Shane Matthew Stephens, Fitzwilliam, NH (US); John Pung Tsan, Spofford, NH (US); Leonard Gerard Wamboldt, Sunderland, MA (US); Kenneth Smith Woodard, New Boston, NH (US)

(21) Appl. No.: 16/599,567

(22) Filed: Oct. 11, 2019

Related U.S. Application Data
(60) Provisional application No. 62/753,304, filed on Oct. 31, 2018.

(51) Int. Cl. G02B 5/08; C23C 14/58; C23C 14/34; G02B 7/182

(52) U.S. Cl. CPC G02B 5/0808; G02B 7/182; C23C 14/34; C23C 14/5886

(57) ABSTRACT

A support for optical elements is described. The support includes a base substrate with high specific stiffness and a finishing layer. The base substrate is Al, an alloy of Al, Mg, or an alloy of Mg. The finishing layer is preferably an alloy of Al and Si. The finishing layer is or is capable of being processed to provide a surface with low finish. Low finish is achieved by diamond turning or polishing the finishing material. The finishing layer has a coefficient of thermal expansion similar to the coefficient of thermal expansion of the base substrate. The optical element optionally includes a reflective stack on the finishing layer.

This application claims the benefit of priority to U.S. Provisional Application Ser. No. 62/753,304 filed on Oct. 31, 2018, the content of which is relied upon and incorporated herein by reference in its entirety.

### FIELD

This description pertains to optical elements. More particularly, this description pertains to optical elements that include a reflective layer on a support having a surface with low finish. Most particularly, this description pertains to supports for optical elements that include a base substrate with high corrosion resistance and a finishing layer with low finish to provide a surface for deposition of thin film reflective coatings.

### BACKGROUND

Optical systems are widely used for sensing, detection, and light sources. Common applications include remote sensing for homeland security, aerospace and defense, laser systems, solar power concentrators, metrology, and optical scanning systems. Optical systems are needed for operation over a variety of wavelengths, including visible (VIS) through long wave infrared (LWIR) wavelengths. As the utility and sensitivity of optical systems improves, it is becoming desirable to deploy them in a wider range of operating environments. In particular, there is a need to develop optical systems with high durability that are capable of operating in harsh environments. Harsh environments include corrosive environments (e.g. salt fog, high alkalinity) and humid environments.

Size, weight and power (SWAP) are key design parameters for optical systems slated for use in applications where portability and mobility are advantageous. Size and weight can be directly impacted by the design of the optical system whereas power is indirectly impacted since lighter systems require less power to move.

Design choices for optical systems are generally based on refractive optical elements or reflective optical elements. When designing lightweight optical systems, several factors favor the use of reflective optical elements. First, minimizing the number of optical elements in a system reduces the weight of the system. Maintaining system performance with fewer elements, however, requires use of optics with precision aspheric or free form surfaces. Such optics are best achieved with materials that can be diamond turned.

Second, size and weight can be reduced in multispectral systems in designs that focus all spectral bands through a single aperture. Due to the wavelength dependence of refractive index, multispectral focusing is difficult to accomplish with refractive optics. Reflective optics, however, can readily focus light over wide spectral ranges to a common focal point.

Third, system weight can be reduced by minimizing the weight of individual optical elements. Light weighting can be achieved, for example, through structural optimizations such as thinning the optical element. Thinning, however, is impractical for refractive optics because refractive power requires sufficient thickness of the optic. The optical effect in reflective optics, in contrast, depends only on the surface region and it is generally possible to thin the substrate supporting the reflective surface to a degree consistent with requirements of mechanical integrity to reduce weight.

Fourth, system weight can be reduced by selecting low density materials for optical elements. The need for transmissivity through refractive optics limits the selection of materials and prevents the use of many desirable substrates. Far fewer limitations apply to substrates for reflective elements. Even if a particular substrate material has poor reflection over a spectral band of interest, it is normally possible to achieve desired performance by depositing a thin reflective film on the surface of the substrate.

Based on the above considerations, reflective optics utilizing low density, structurally optimized, and corrosion-resistant mirrors that feature surfaces amenable to diamond turning to achieve low finish are the preferred design choice for portable wide or multiband optical systems.

As new applications emerge, more demanding requirements are imposed on reflective optical elements. There is currently a need for lightweight reflective optical elements that can maintain precise figure under dynamic conditions for both aerospace and commercial applications. For commercial applications, high speed scanners require lightweight mirrors to maintain the flatness of the reflective surface under extreme oscillating or rotating acceleration loads. For airborne surveillance and targeting applications, lightweight mirrors are required to maintain accurate figure in the vibratory and thermal environments aircraft vibration and thermal environments. For space applications, lightweight mirrors are required to maintain accurate figure under various actuating and/or spacecraft accelerations and thermal environments. For spacecraft, weight is also a major consideration due to the cost per pound of launching a satellite into space. Also, for space environments, materials that block cosmic radiation are often an advantage and/or are required to protect the detectors.

The need for lightweight mirrors that maintain precise figure under demanding conditions has motivated a search for new low-density substrates that exhibit high stiffness and high resistance to corrosion.

### SUMMARY

The present disclosure provides a support for reflective optical elements and reflective optical elements that include the support. The support includes a base substrate and a finishing layer. The base substrate comprises Al, an alloy of Al, Mg, or an alloy of Mg. A finishing layer is a layer with, or capable of being processed to, a lower surface roughness than the base substrate. The finishing layer preferably has, or is capable of being processed to have, a finish less than 25 Å RMS (root-mean-square) roughness. When the finishing layer is processed, the finishing layer includes a surface with a finish less than 25 Å RMS (root-mean-square) roughness and/or less than 1000 Å PV (peak-to-valley) roughness. The finishing layer has a coefficient of thermal expansion (CTE) within ±20% of the coefficient of thermal expansion (CTE) of the base substrate. Preferred finishing layers are alloys of Al with Si and, in particular, binary alloys of Al and Si. Methods of processing the finishing layer include diamond turning, magnetorheological finishing, and polishing. The optical element optionally includes a reflective layer on the finishing layer. Methods for forming the finishing layer on the base substrate are also described.

The present disclosure extends to:

An optical element comprising:
a base substrate, the base substrate comprising Al, an alloy of Al, Mg, or an alloy of Mg; and
a finishing layer in contact with the base substrate, the finishing layer comprising an alloy of Al and Si.

Additional features and advantages will be set forth in the detailed description which follows, and in part will be readily apparent to those skilled in the art from the description or recognized by practicing the embodiments as described in the written description and claims hereof, as well as the appended drawings.

It is to be understood that both the foregoing general description and the following detailed description are merely exemplary, and are intended to provide an overview or framework to understand the nature and character of the claims.

The accompanying drawings are included to provide a further understanding, and are incorporated in and constitute a part of this specification. The drawings are illustrative of selected aspects of the present description, and together with the specification serve to explain principles and operation of methods, products, and compositions embraced by the present description. Features shown in the drawing are illustrative of selected embodiments of the present description and are not necessarily depicted in proper scale.

### BRIEF DESCRIPTION OF THE DRAWINGS

While the specification concludes with claims particularly pointing out and distinctly claiming the subject matter of the written description, it is believed that the specification will be better understood from the following written description when taken in conjunction with the accompanying drawings, wherein:

FIG. 1 shows CTE (coefficient of thermal expansion) at room temperature as a function of wt % Si in a binary Si—Al alloy.

FIG. 2 shows the RMS roughness of finishing layers made from Al and various Al—Si alloys on a base substrate made from T6 6061 Al.

FIG. 3 shows a surface image of an Al—Si finishing layer on a 6061 Al base substrate obtained during measurement of figure.

FIG. 4 shows an Euler map of the surface of a finishing layer (100 wt % Al) on a 6061 Al base substrate.

FIG. 5 shows an Euler map of the surface of a finishing layer (99 wt % Al/1 wt % Si) on a 6061 Al base substrate.

FIG. 6 shows an Euler map of the surface of a finishing layer (90 wt % A./10 wt % Si) on a 6061 Al base substrate.

FIG. 7 shows pole figure map of the surface of a finishing layer (100 wt % Al) on a 6061 Al base substrate.

FIG. 8 shows a pole figure map of the surface of a finishing layer (99 wt % Al/1 wt % Si) on a 6061 Al base substrate.

FIG. 9 shows a pole figure map of the surface of a finishing layer (90 wt % Al/10 wt % Si) on a 6061 Al base substrate.

FIG. 10 shows an SEM image of the surface of a finishing layer (100 wt % Al) on a 6061 Al base substrate.

FIG. 11 shows an SEM image of the surface of a finishing layer (99 wt % Al/1 wt % Si) on a 6061 Al base substrate.

FIG. 12 shows an SEM image of the surface of a finishing layer (90 wt % Al/10 wt % Si) on a 6061 Al base substrate.

FIG. 13 shows an AFM image of the surface of a finishing layer (90 wt % Al/10 wt % Si) on a 6061 Al base substrate.

FIG. 14 shows an AFM image of the surface of a finishing layer (80 wt % Al/20 wt % Si) on a 6061 Al base substrate.

FIG. 15 shows an SEM image of the surface of a finishing layer (35 wt % Al/65 wt % Si) on a 6061 Al base substrate.

FIG. 16 shows a close up of the SEM image shown in FIG. 15.

The embodiments set forth in the drawings are illustrative in nature and not intended to be limiting of the scope of the detailed description or claims. Whenever possible, the same reference numeral will be used throughout the drawings to refer to the same or like feature.

### DETAILED DESCRIPTION

The present disclosure is provided as an enabling teaching and can be understood more readily by reference to the following description, drawings, examples, and claims. To this end, those skilled in the relevant art will recognize and appreciate that many changes can be made to the various aspects of the embodiments described herein, while still obtaining the beneficial results. It will also be apparent that some of the desired benefits of the present embodiments can be obtained by selecting some of the features without utilizing other features. Accordingly, those who work in the art will recognize that many modifications and adaptations are possible and can even be desirable in certain circumstances and are a part of the present disclosure. Therefore, it is to be understood that this disclosure is not limited to the specific compositions, articles, devices, and methods disclosed unless otherwise specified. It is also to be understood that the terminology used herein is for the purpose of describing particular aspects only and is not intended to be limiting.

Disclosed are components (including materials, compounds, compositions, and method steps) that can be used for, in conjunction with, in preparation for, or as embodiments of the disclosed reflective optical elements and methods for making reflective optical elements. It is understood that when combinations of component are disclosed, each component individually and each sub-combination of two or more components is also contemplated and disclosed herein even if not explicitly stated. If, for example, if a combination of components A, B, and C is disclosed, then each of A, B, and C is individually disclosed as is each of the sub-combinations A-B, B-C, A-C, and A-B-C. This concept applies to all aspects of this disclosure including, but not limited to, components corresponding to materials, compounds, compositions, and steps in methods.

In this specification and in the claims which follow, reference will be made to certain terms that are defined as follows:

As used herein, contact refers to direct contact or indirect contact. Elements in direct contact touch each other. Elements in indirect contact do not touch each other, but are joined through one or more intervening materials. Elements in contact may be rigidly or non-rigidly joined. Contacting refers to placing two elements in direct or indirect contact. Elements in direct (indirect) contact may be said to directly (indirectly) contact each other.

Ordering of layers in a sequence of layers in the present optical elements will be described relative to the base substrate. Description of the ordering of the layers herein is irrespective of the orientation of the base substrate.

Unless otherwise specified herein, the terms “finish” or “surface finish” or “roughness” or “surface roughness” refer to the RMS (root-mean-square) roughness and/or PV (peak-to-valley) roughness of a surface. RMS roughness and PV roughness are measured by interferometry or atomic force microscopy (AFM). In selected examples described herein, the roughness parameters R_{q} and Rₐ known in the art are determined from AFM. A surface with low roughness is said to have a low finish and a surface with high roughness is said to have a high finish. Optical surfaces with low finish are smoother and are preferable for the optical elements described herein.

The term “layer” refers to a region of uniform composition and uniform optical properties. A planar layer is a layer with uniform thickness on a planar surface.

The term “stack” refers to a combination of two or more layers. A planar stack is a stack with two or more planar layers.

Average grain size is reported as equivalent diameter, where equivalent diameter refers to the diameter of a circle having an area equivalent to the area of a grain. The area of grains is determined from SEM images.

Reference will now be made in detail to illustrative embodiments of the present description.

The present description provides a support for reflective optical elements. The support has light weight, high specific stiffness, and a finishing layer with a low finish or a finishing layer capable of being processed to a low finish. The present description also provides reflective optical elements utilizing the support. The reflective optical element may also include a reflective layer or a reflective stack on the finishing layer of the support. A reflective stack is a combination of two or more layers that cooperate to provide reflection or other optical effect.

The support includes a base substrate and a finishing layer on the base substrate. The finishing layer is in direct or indirect contact with the base substrate. As used herein, finishing layer refers to a layer that improves (lowers) the finish of the base substrate. Base substrates that are light weight are often made from materials having rough surfaces that are difficult to finish to low roughness. A finishing layer is a layer added to the surface of a base substrate that has a surface that has (upon deposition), or is capable of being processed to have (subsequent to deposition), a lower finish than the surface (processed or not) of the base substrate. The finishing layer is applied to a processed or unprocessed surface of a base substrate. The finishing layer has a finish lower than the finish of the processed or unprocessed surface of the base substrate and provides a smoother surface for deposition of subsequent layers (e.g. a reflective layer). The finish of the surface of the finishing layer is lower than the finish of the processed or unprocessed surface of the base substrate upon deposition of the finishing layer and/or upon processing the surface of the finishing layer after deposition. Preferably, the finishing layer has a surface capable of being processed to a finish less than 25 Å RMS (root-mean-square) roughness or is a layer with a surface having a finish less than 25 Å RMS (root-mean-square) roughness in its as-deposited state. One or more additional layers (e.g. reflective layer, adhesion layer, tuning layer, and/or protective layer) are optionally in contact with the finishing layer.

The support may also include one or more intervening layers between the finishing layer and the base substrate. The one or more intervening layers may include an adhesion layer that improves adhesion of the finishing layer to the base substrate.

Selection of the base substrate is motivated by the design objectives of light weight and retention of figure in mechanically demanding applications. Relevant properties guiding selection of the base substrate material include coefficient of thermal expansion (CTE), dimensional stability, environmental compatibility (corrosion, radiation), finishing capabilities (e.g. ability to diamond turn and/or polish to optical quality); compatibility with reflective coatings, specific stiffness, density, and cost.

Aluminum (Al) and alloys of aluminum are desirable materials for the base substrate due to their relatively low cost, manufacturability, strength and light weight. Magnesium (Mg) and alloys of magnesium are also desirable materials for base substrates because they offer high strength and are less dense than aluminum or alloys of aluminum. Although aluminum, alloys of aluminum, magnesium, and alloys of magnesium have favorable strength and weight properties, they have proven difficult to finish to low roughness.

By way of example, a widely used base substrate material for reflective optics is an aluminum alloy, T6 6061-Al. T6 6061-Al alloy nominally contains 95.8-98.6 wt % Al, 0.04-0.35 wt % Cr, 0.15-0.4 wt % Cu, 0.8-1.2 wt % Mg, 4-0.6.0 wt % Si, and may additionally contain up to 0.75 wt % Fe, 0.155 wt % Mn, 0.155 wt % Ti, 0.255 wt % Zn, and other residual elements (up to 0.05 wt % of any one residual element, with the collective amount of all other residual elements not exceeding 0.155 wt %).

Analysis of the microstructure of T6 6061-Al alloy reveals the presence of intermetallic particles in the material. The presence of intermetallic particles is believed to be responsible for two significant drawbacks that limit the application of T6 6061-Al alloy. First, the intermetallic particles contribute to roughness on the surface and lead to a decrease in reflected intensity and optical throughput due to scattering losses. The intermetallic particles degrade the quality of the surface and cannot be eliminated by polishing. Second, the intermetallic particles, or the grain boundaries associated with them, constitute sites of high reactivity that make T6 6061-Al alloy susceptible to corrosion.

Electrochemical nickel plating and aluminum plating processes have been developed recently in an effort to improve the durability of aluminum alloys in harsh environments. Nickel plating of the surface of aluminum alloys has been demonstrated to enhance corrosion resistance. Plated nickel also provides a homogenous plating surface and can be finished to a surface roughness in the range of 10-20 Å RMS (root-mean-square). The net effect of the homogeneous plating and the low surface finish improves corrosion resistance and provides a high quality surface for deposition of a reflective layer. Unfortunately, due to the thickness of the plated Ni surface layer in conjunction with the CTE (coefficient of thermal expansion) mismatch between aluminum alloy base substrates (including T6 6061-Al, other 6061 Al alloys, and other series 6000 Al alloys) and the plated Ni layer, the operational temperature range of nickel-plated base substrates is limited in deployment environments experiencing large variations in temperature, especially where figure requirements (e.g. surface wavefront distortion, surface flatness and/or surface curvature) are demanding.

Amorphous silicon and nickel-chromium surface layers have also been used to achieve low roughness surface finishes on 6061-Al and can circumvent concerns over CTE mismatch if the layer thickness is kept below 1 μm. However, these coatings have intrinsic stresses that prevent the use of this technology on mirrors with a high aspect ratio. In addition, the thickness limitation of amorphous silicon and nickel-chromium surface layers needed to avoid CTE mismatch problems limits the corrosion resistance properties of these layers. While polishing the surface of 6061-Al coated with amorphous silicon or nickel-chromium layer can result in a low surface finish (ca. 10 Å RMS roughness), bi-directional reflective distribution function (BRDF) scattering tests indicate that the resulting surface effectively performs as if it had a 60 Å RMS surface finish because the surface peak-to-valley variations remain high as a result of impurities.

Low surface finish is desired because roughness present on the surface of a support is replicated in layers formed on the support. To maximize the reflection of reflecting optical elements, it is essential to minimize the roughness of the reflecting surface. The presence of roughness on a reflecting surface leads to deleterious effects such as distortion of the optical signal, scattering, diffuse reflectance, or a reduction in optical efficiency.

In applications requiring high stability of figure in mechanically demanding deployment environments, it has heretofore been challenging to find a suitable material for the finishing layer for supports that include base substrates made with Al, alloys of Al, Mg and alloys of Mg. Materials currently used as finishing layers with these base substrates have poor CTE match or are difficult to finish to low roughness. Al, for example, has good CTE match with Al alloys, but is difficult to finish to low roughness because it is a soft and ductile material prone to forming burrs when machined. This description provides supports with finishing layers that can be processed to a low finish that also exhibit good CTE match to base substrates made with Al, alloys of Al, Mg, and alloys of Mg.

A support for optical elements is described herein. The support includes a base substrate and a finishing layer. The base substrate is Al, an alloy of Al, Mg, or an alloy of Mg. The alloy of Al includes Al in an amount of at least 80 wt %, or at least 85 wt %, or at least 90 wt %, or at least 95 wt %, or in the range from 80 wt %-99 wt %, or in the range from 85 wt %-98 wt %, or in the range from 88 wt %-97 wt %. Preferred alloys of Al include 6061 Al (e.g. T6 6061-Al and other tempered forms of 6061 Al) and other series 6000 Al alloys. The alloy of Mg includes Mg in an amount of at least 80 wt %, or at least 85 wt %, or at least 90 wt %, or at least 95 wt %, or in the range from 80 wt %-99 wt %, or in the range from 85 wt %-98 wt %, or in the range from 88 wt %-96 wt %. Representative alloys of Mg include AZ80A, AZ31B, and ZK60A. Compositions of these alloys are shown in Table 1 below. In some embodiments, the substrate includes intermetallic particles.

TABLE 1
Compositions of Selected Mg Alloy Substrate Materials

| Element | AZ80A | AZ31B | ZK60A |
|---|---|---|---|
| Mg | ~91.3 | 95.0-96.6 | 94 |
| Al | 8.2 | 2.5-3.5 | |
| Zn | 0.38 | 0.7-1.3 | 4.8-6.2 |
| Mn | 0.14 | ≥0.2 | |
| Si | 0.01 | ≤0.05 | |
| Cu | | ≤0.05 | |
| Fe | 0.004 | ≤0.005 | |
| Ni | 0.0007 | ≤0.005 | |
| Zr | | | ≥0.45 |
| Other | <0.03 | ≤0.30 | |

The base substrate has an aspect ratio of at least 1:1, or at least 2:1, or at least 5:1, or at least 10:1, or at least 20:1. The base substrate is formed by casting, by machining plate or bar stock, by additive manufacturing, or by direct metal laser sintering. In one embodiment, the base substrate is configured to have an optical surface with near net shape.

In one embodiment, the finishing layer has a surface with a finish less than 25 Å RMS (root-mean-square) roughness. In another embodiment, the finishing layer lacks a surface with a finish less than 25 Å RMS (root-mean-square) roughness, but is capable of being processed to a finish less than 25 Å RMS (root-mean-square) roughness. That is, in its as-deposited state, the finishing layer may have a finish greater than 25 Å RMS (root-mean-square) roughness. The finishing layer, however, is composed of a material that is capable of being processed after deposition to a finish less than 25 Å RMS (root-mean-square) roughness.

To further clarify and elucidate embodiments: upon deposition, the finishing layer may or may not have a surface finish less than 25 Å RMS (root-mean-square) roughness. In some embodiments, the finishing layer is processed after deposition to include a surface with a finish less than 25 Å RMS (root-mean-square) roughness, or a surface with a finish less than 20 Å RMS (root-mean-square) roughness, or a surface with a finish less than 15 Å RMS (root-mean-square) roughness, or a finish less than 10 Å RMS (root-mean-square) roughness, or a finish less than 5 Å RMS (root-mean-square) roughness, or a surface with a finish in the range from 3 Å RMS (root-mean-square) roughness-25 Å RMS (root-mean-square) roughness, or a surface with a finish in the range from 4 Å RMS (root-mean-square) roughness-20 A RMS (root-mean-square) roughness, or a surface with a finish in the range from 5 Å RMS (root-mean-square) roughness-15 Å RMS (root-mean-square) roughness.

In one embodiment, the finishing layer has a surface with a finish less than 1000 Å PV (peak-to-valley) roughness. In another embodiment, the finishing layer lacks a surface with a finish 1000 Å PV (peak-to-valley) roughness, but is capable of being processed to a finish less than 1000 Å PV (peak-to-valley) roughness. That is, in its as-deposited state, the finishing layer may have a finish greater than 1000 Å PV (peak-to-valley) roughness. The finishing layer, however, is composed of a material that is capable of being processed after deposition to a finish less than 1000 Å PV (peak-to-valley) roughness.

To further clarify and elucidate embodiments: upon deposition, the finishing layer may or may not have a surface finish less than 1000 Å PV (peak-to-valley) roughness. In some embodiments, the finishing layer is processed after deposition to include a surface with a finish less than 500 Å PV (peak-to-valley) roughness, or a surface with a finish less than 300 Å PV (peak-to-valley) roughness, or a surface with a finish less than 100 Å PV (peak-to-valley) roughness, or a surface with a finish less than 60 Å PV (peak-to-valley) roughness, or a surface with a finish less than 30 Å PV (peak-to-valley) roughness, or a surface with a finish in the range from 20 Å PV (peak-to-valley) roughness-1000 Å PV (peak-to-valley) roughness, or a surface with a finish in the range from 30 Å PV (peak-to-valley) roughness-500 Å PV (peak-to-valley) roughness, or a surface with a finish in the range from 50 Å PV (peak-to-valley) roughness-250 Å PV (peak-to-valley) roughness.

Techniques for processing the finishing layer to reduce RMS (root-mean-square) and PV (peak-to-valley) roughness include diamond turning, magnetorheological polishing, polishing with an abrasive slurry, ion beam figuring, deterministic polishing, and combinations thereof. In one embodiment, the finishing layer is diamond turned and then polished. The same processing techniques are optionally used to process the surface of the base substrate to reduce its finish prior to deposition of the finishing layer. Representative abrasive slurries include slurries with colloidal silica or other colloidal oxide (e.g. colloidal metal oxides). Computer controlled polishing (CCP) is a preferred polishing technique.

Some preferred finishing layer is an alloy of Al and Si that includes Al in an amount greater than 82.5 wt %, or greater than 85.0 wt %, or greater than 90.0 wt %, or greater than 95.0 wt %, or in the range from 82.5 wt %-99.5 wt %, or in the range from 85.0 wt %-99.0 wt %, or in the range from 87.5 wt %-098.5 wt %, or in the range from 90.0 wt %-98.0 wt % and Si in an amount less than 17.5 wt %, or less than 15.0 wt %, or less than 12.5 wt %, or less than 10.0 wt %, or less than 7.5 wt %, or less than 5.0 wt %, or at least 0.1 wt %, or at least 0.5 wt %, or at least 1.0 wt %, or at least 2.0 wt %, or at least 3.0 wt %, or at least 5.0 wt %, or at least 7.5 wt %, or at least 10.0 wt %, or in the range from 0.1 wt %-17.5 wt %, or in the range from 0.3 wt %-16.0 wt %, or in the range from 0.5 wt %-15.0 wt %, or in the range from 1.0 wt %-14.0 wt %, or in the range from 2.0 wt %-11.0 wt %, or in the range from 5.0 wt %-12.0 wt %, or in the range from 7.0 wt %-11.0 wt %. The alloy of Al and Si is preferably a binary alloy of Al and Si

In other preferred embodiments, the finishing layer is an alloy of Al and Si that includes Al in an amount less than 77.5 wt %, or less than 75.0 wt %, or less than 70.0 wt %, or less than 60.0 wt %, or less than 55.0 wt %, or less than 50.0 wt %, or less than 45.0 wt %, or less than 40.0 wt % and greater than 20.0 wt %, or greater than 25.0 wt %, or greater than 30.0 wt %, or greater than 35.0 wt %, or in the range from 20.0 wt %-77.5 wt %, or in the range from 25.0 wt %-70.0 wt %, or in the range from 30.0 wt %-60.0 wt %, or in the range from 35.0 wt %-55.0 wt % and Si in an amount greater than 25.0 wt %, or greater than 35 wt %, or greater than 40.0 wt %, or greater than 50.0 wt %, or greater than 55.0 wt %, or greater than 60.0 wt %, or greater than 65.0 wt %, or less than 80.0 wt %, or less than 75.0 wt %, or less than 70.0 wt %, or in the range from 25.0 wt %-80.0 wt %, or in the range from 35.0 wt %-75.0 wt %, or in the range from 45.0 wt %-70.0 wt %, or in the range from 50.0 wt %-65.0 wt %. The alloy of Al and Si is preferably a binary alloy of Al and Si.

In other preferred embodiments, the finishing layer is a binary alloy of Al and Si, or an alloy that consists essentially of Al and Si with a composition consistent with the compositions listed herein.

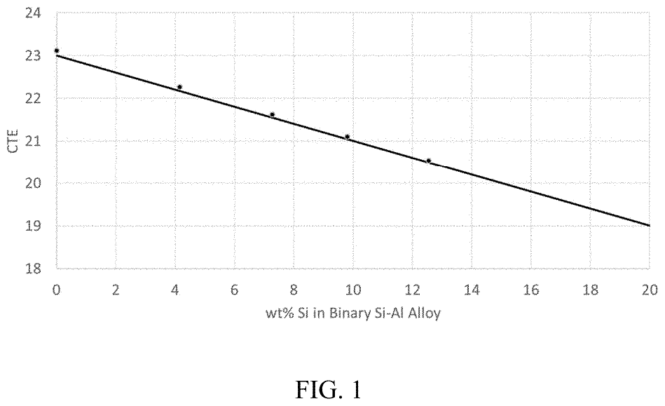

Al has a higher coefficient of thermal expansion (CTE) than Si and by alloying Al with Si, the coefficient of thermal expansion can be precisely controlled to provide a close CTE match with base substrates made with Al, alloys of Al, Mg or alloys of Mg, or carbides (boron carbide, silicon carbide), or nitrides (e.g. boron nitride, silicon nitride). The CTE of pure Al is about 23 ppm/K at room temperature. Alloying Al with Si reduces the CTE approximately linearly with Si concentration (in wt %). For every 10 wt % Si in the alloy, the CTE is reduced by approximately 2 ppm/K. For example, an alloy containing 10 wt % Si and 90 wt % Al has a CTE of approximately 21 ppm/K and an alloy containing 20 wt % Si and 80 wt % Al has a CTE of approximately 19 ppm/K. FIG. 1 shows CTE as a function of Si concentration (wt %) at room temperature for binary Al—Si alloys. By controlling the Si concentration in the alloy, CTE can be varied over a wide range to provide a good CTE match with a particular substrate, while achieving the low finish described herein.

Factors other than CTE are also important considerations for the finishing layer. For example, structure and hardness of the finishing layer are important for achieving low finish and maintaining figure.

Techniques for forming the finishing layer include PVD (physical vapor deposition), CVD (chemical vapor deposition), sputtering, co-sputtering, evaporation, and plating. The finishing layer preferably has an amorphous structure or crystalline structure with a small grain size in its as-deposited state. The finishing layer is in direct or indirect contact with the base substrate.

The thickness of the finishing layer is in the range from 20 μm-400 μm, or in the range from 30 μm-300 μm, or in the range from 50 μm-250 μm, or in the range from 80 μm-200 μm. As noted above, the finishing layer includes a surface that may or may not have been processed to reduce the finish. Processing to reduce the finish includes removal of a portion of the finishing layer. When processing is required or desired, the thickness of the finishing layer at the time of deposition can be adjusted to account for the anticipated removal of material needed to achieve a particular finish. The thicknesses of the finishing layer described herein refer to the thickness of the finishing layer in its as-deposited state or when the finishing layer is in a state having a finish (RMS (root-mean-square) roughness or PV (peak-to-valley) roughness) within the values specified herein. Processing of the finishing layer by diamond turning and/or polishing typically reduces the thickness of the finishing layer by 25 Å-125 Å relative to the thickness of the finishing layer in its as-deposited state. In embodiments in which the finishing layer includes a processed surface, the as-deposited thickness can be increased to account for loss of material upon processing to provide a finishing layer with a processed surface having a thickness disclosed above.

To minimize thermal stresses between the finishing layer and the base substrate in applications in which the optical element is subjected to thermal cycling over wide temperature ranges, it is preferable for the finishing layer to have a coefficient of thermal expansion that closely matches the coefficient of thermal expansion of the base substrate. In various aspects, the coefficient of thermal expansion of the finishing layer is within ±20% of the coefficient of thermal expansion of the base substrate, or within ±15% of the coefficient of thermal expansion of the base substrate, or within ±10% of the coefficient of thermal expansion of the base substrate, or within ±5% of the coefficient of thermal expansion of the base substrate, or within ±2.5% of the coefficient of thermal expansion of the base substrate, or within ±1% of the coefficient of thermal expansion of the base substrate. For example, if the coefficient of thermal expansion of the base substrate is 10 ppm/° C. (10×10⁻⁶/° C.) and the coefficient of thermal expansion of the finishing layer is within ±20% of the coefficient of thermal expansion of the base substrate, the coefficient of thermal expansion of the finishing layer is in the range from 8 ppm/° C. and 12 ppm/° C., which range corresponds to 10 ppm/° C.±20%.

In one aspect, the finishing layer is in direct contact with the base substrate. In another aspect, an interface layer is disposed between the base substrate and the finishing layer, where the interface layer is in direct contact with the base substrate and the finishing layer is in direct contact with the base substrate.

In one aspect, the support disclosed herein functions as a support for an optical element that includes a variety of reflective layers or reflective stacks formed on the finishing layer. The reflective coating preferably provides high reflectivity in one or more of the visible (VIS) (400 nm-700 nm), near infrared (NIR) (700 nm-1 μm), shortwave infrared (SWIR) (1 μm-3 μm), midwave infrared (MWIR) (3 μm-8 μm), and long wave infrared (LWIR) (8 μm-15 μm) bands. The reflective coating is a layer of a single material or a multilayer stack of two or more materials. In one embodiment, the reflective coating includes a reflective layer and one or more tuning layers. The reflective coating optionally includes a barrier layer, one or more interface layers, and one or more protective layers. When present, the one or more protective layers overlie the other layers in the stack.

Representative reflective layers include a metal layer, such as a transition metal layer. The reflective layer preferably has high reflectivity at wavelengths in the VIS, NIR, SWIR, MWIR, and/or LWIR spectral bands. The reflective metal is an elemental metal or a metal alloy. Exemplary reflective layers include one or more elements selected from the group consisting of Ag, Au, Al, Rh, Cu, Pt and Ni. The thickness of a reflective metal layer is in the range from 75 nm-350 nm, or in the range from 80 nm-150 nm, or in the range from 90 nm-120 nm.

The reflective coating optionally includes one or more tuning layers. The one or more tuning layers are positioned between a protective layer of the reflective coating and the finishing layer. In one embodiment, the tuning layer(s) are positioned between a reflective layer and a protective layer(s) of the reflective coating. Tuning layer(s) are designed to optimize reflection in defined wavelength regions. Tuning layer(s) typically include an alternating combination of high and low refractive index materials, or high, intermediate, and low refractive index materials. Materials used for tuning layers are preferably low absorbing in the wavelength range of from 0.4 μm-15.0 μm. Representative materials for tuning layers include YbF₃, GdF₃, YF₃, YbOₓF_{y}, GdF₃, Nb₂O₅, Bi₂O₃, and ZnS. The tuning layer(s) have a thickness in the range of 75 nm-300 nm. In one embodiment, the reflective coating includes YbF₃ and ZnS as tuning layers.

In some aspects, a reflective layer and a tuning layer are in direct contact and in other aspects, one or more interface layers are present between a reflective layer and a tuning layer. The interface layer(s) promote adhesion or provide galvanic compatibility between the reflective layer and tuning layer. The interface layer(s) needs to have a thickness sufficient for adhesion, but must also be thin enough to minimize absorption of light reflected from the reflective layer. The interface layer(s) positioned between the reflective layer and the tuning layer(s) have a thickness in the range of 5 nm-20 nm, or 8 nm-15 nm, or 8 nm-12 nm. The interface layer(s) positioned between the reflective layer and a tuning layer include one or more of Nb₂O₅, TiO₂, Ta₂O₅, Bi₂O₃, ZnS and Al₂O₃.

In one embodiment, the reflective layer is in direct contact with the finishing layer. In another embodiment, the optical element includes a barrier layer and/or an interface layer between the reflective layer and the finishing layer. In still another embodiment, the optical element includes a barrier layer in direct contact with the finishing layer. In yet another embodiment, the optical element includes a barrier layer in direct contact with the finishing layer and an interface layer in direct contact with the barrier layer. The interface layer promotes adhesion between the reflective layer and barrier layer, or between the reflective layer and the galvanic-compatibility layer. In some aspects, the interface layer insures galvanic compatibility of the reflective coating with the finishing layer, or galvanic compatibility of the barrier layer with the reflective layer. In some aspects, the barrier layer insures galvanic compatibility between the reflective layer and the base substrate. In other aspects, the barrier layer prevents corrosion of the reflective layer when the optical element is exposed to humidity or salt fog.

Representative barrier layers include Si₃N₄, SiO₂, TiAlN, TiAlSiN, TiO₂, DLC (diamond-like carbon), Al, CrN, and SiₓN_{y}O_{z}. The barrier layer has a thickness in the range from 100 nm-50 μm, or in the range from 500 nm-10 μm, or in the range from 1 μm-5 μm. The thickness of the barrier layer can also be adjusted to accommodate changes in temperature without distorting the figure of the optical element. Thermal stresses increase as the operational temperature range increases, so thinner barrier layers are recommended to avoid figure distortion in deployment environments experiencing large swings in temperature. Thicker barrier layers, however, provide better resistance to corrosion.

Representative interface layers positioned between the finishing layer and a reflective layer include one or more of Ni, Cr, Ni—Cr alloys (e.g. Nichrome), Ni—Cu alloys (e.g. Monel), Ti, TiO₂, ZnS, Pt, Ta₂O₅, Nb₂O₅, Al₂O₃, AlN, AlOₓN_{y}, Bi, B₂O₃, Si₃N₄, SiO₂, SiOₓN_{y}, DLC (diamond-like carbon), MgF₂, YbF₃, and YF₃. The interface layer has a thickness in the range from 0.2 nm-25 nm, where the lower end of the thickness range (e.g. 0.2 nm-2.5 nm, or 0.2 nm-5 nm) is appropriate when the interface layer is a metal (to prevent parasitic absorbance of light passing through the reflective coating) and the higher end of the thickness range (e.g. 2.5 nm-25 nm, or 5 nm-25 nm) is appropriate when the interface layer is a dielectric.

The protective layer provides resistance to scratches, resistance to mechanical damage, and chemical durability. Representative materials for the protective layer include YbF₃, YbFₓO_{y}, YF₃ and Si₃N₄. The protective layer(s) is the top layer of the reflective coating. The protective layer(s) have a thickness in the range of 60 nm-200 nm.

### EXAMPLES

The following examples present surface finish and figure results for several supports with a base substrate made from 6061 Al and a finishing layer made from an alloy of Al and Si. Comparative samples using a base substrate made from 6061 Al without a finishing layer were also investigated. In all of the samples with finishing layers discussed below, the finishing layer was deposited on the base substrate using a co-sputtering technique (DC magnetron) using pure Al and pure Si as targets. Power for the Al magnetron target and Si magnetron target were adjusted to obtain various Al/Si ratios in the Al—Si alloys. After deposition, each finishing layer was processed first by diamond turning (single point) and then polished with a Zeeko IRP 600 polisher using a slurry consisting of 95 vol. % colloidal silica (0.02 μm particle size) and 5 vol. % surfacing additive (Universal Photonics Everflo). Polishing was performed at 20° C. and 14.5 psi for 10-20 min (per inch of sample).

Surface figure was measured with an interferometer (Zygo Verifier XPZ equipped with a HeNe laser light source with a wavelength of 632.8 nm). The interferometer was set-up using a 1/20^{th} wave, 4-inch, Dynaflect transmission flat and MetroPro 9 software. The measured system analysis (MSA) resulted in an RMS standard deviation of 0.002 waves for 10 individual measurements each consisting of 3 phase averages. The standard error was 0.0006 waves RMS. The measurement configuration included no filters, no error subtractions, removal of piston and tilt, and full surface measurement with no masks. In the interferometric analysis, figure is assessed by counting interference fringes. Two fringes correspond to a wavelength of the interrogating light (632.8 nm) and define the dimension “waves” used herein to characterize the figure of a surface.

Zygo New View surface profilometers (model 600 or 7300) or AFM (atomic force microscopy), as indicated below, were used to measure surface finish (RMS roughness and PV roughness). The measurements completed with the Zygo profilometers were based on interferometry. The profilometer instruments were equipped with a 20× objective set at 1× magnification. The measurement configuration included removal of spike height (xRMS) 2.50, scan length 10μ bipolar (3 sec), filters were off, and camera resolution 320×240 pixels resolution at frame rate 72 hz (New View 600) and 992×992 pixels at frame rate 48 hz (New View 7300). Finish was measured at several positions on the surface. The finish and PSD (power spectral density) data was representative of the entire surface. To flatten the data, all terms were subtracted from the data including 4th order Zernikes, no filtering or masks were used.

Scratch and dig performance was obtained for several samples using the procedure described in Military Specification MIL-O-13830A (11 Sep. 1963).

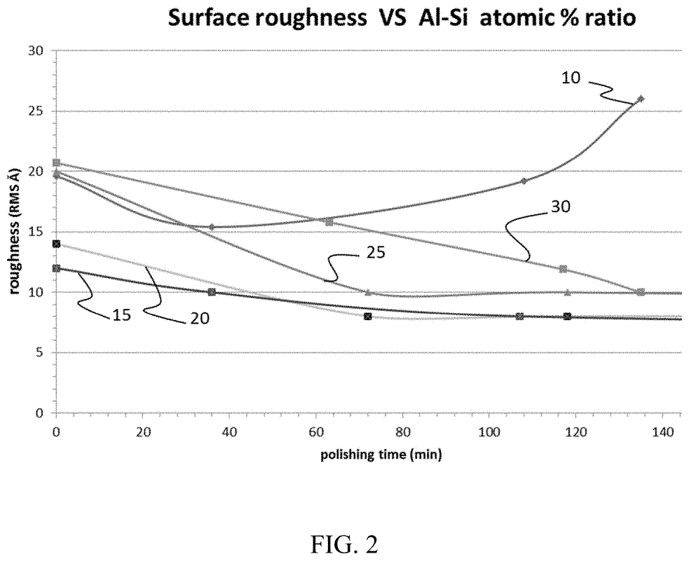

FIG. 2 shows the surface roughness of a series of finishing layers on a base substrate after polishing. The base substrate was 6061 Al. Al and several Al—Si alloys were used as finishing layers. The thickness of the finishing layers was between 30 μm and 150 μm. After deposition, the finishing layers were diamond turned and then polished with a colloidal silica slurry. Samples with different polishing times for each alloy composition were prepared.

The results are shown in FIG. 2 for several alloy compositions over a range of polishing times. The finishing layers included pure Al (Trace 10), an alloy of Al and Si including 80 wt % Al and 20 wt % Si (Trace 15), an alloy of Al and Si including 90 wt % Al and 10 wt % Si (Trace 20), an alloy of Al and Si including 95 wt % Al and 5 wt % Si (Trace 25), an alloy of Al and Si including 99 wt % Al and 1 wt % Si (Trace 30). FIG. 2 indicates that inclusion of Si in the alloy leads to a significant reduction in RMS roughness of the finishing layer. RMS roughness less than 15 Å was achievable even when small amounts of Si were included in the alloy. Finishing layers that included Al and Si exhibited a reduction in RMS roughness with increasing polishing time. Pure Al, in contrast, showed a deterioration in RMS roughness as polishing time increased.

Table 1 summarizes finish, figure, and scratch/dig results for several supports. The finish data (RMS and PV roughness) reported in Table 1 were obtained by interferometry with a profilometer. The base substrate for each support was 6061 Al. Supports with and without a finishing layer were examined in flat and powered configurations. The finishing layer was an alloy of Al and Si that included 90 wt % Al and 10 wt % Si. Small (2″), medium (4″), and large (6″) supports were tested. The results indicate a significant reduction in finish (RMS roughness and PV roughness), figure and scratch/dig when an Al—Si finishing layer is included.

TABLE 1

| | | Base Substrate: 6061 Al | | | |
|---|---|---|---|---|---|
| | | Finishing Layer: | | Finishing Layer: | |
| | | None | | 90/10 Al/Si | |
| | | Powered | Flat | Powered | Flat |
| Small | Finish (Å RMS) | >30 | >30 | <10 | <10 |
| Optic 2″ | Finish (Å PV) | >1000 | >1000 | <100 | <100 |
| | Figure | 0.03 | 0.03 | 0.02 | 0.01 |
| | (waves RMS) | | | | |
| | Scratch/Dig | 60/40 | 60/40 | 20/10 | 20/10 |
| Medium | Finish (Å RMS) | 40 | 40 | <10 | <10 |
| Optic 6″ | Finish (Å PV) | >5000 | >5000 | <100 | <100 |
| | Figure | 0.04 | 0.04 | 0.02 | 0.01 |
| | (waves RMS) | | | | |
| | Scratch/Dig | 60/40 | 60/40 | 20/10 | 20/10 |
| Large | Finish (Å RMS) | 60 | 60 | <15 | <15 |
| Optic | Finish (Å PV) | >5000 | >5000 | <150 | <150 |
| 12-24″ | Figure | 0.1 | 0.1 | 0.03 | 0.03 |
| | (waves RMS) | | | | |
| | Scratch/Dig | 60/40 | 60/40 | 40/20 | 40/20 |

Table 2 summarizes surface finish (RMS roughness and PV roughness as determined by interferometry) and scratch/dig results for supports configured as 6″ parabolic mirrors. All supports included 6061 Al as the base substrate. Examples with and without a finishing layer were examined. Finishing layers made from several Al—Si alloys were considered. After deposition, the finishing layers were processed by diamond turning followed by polishing with a silica slurry. The results indicate a significant reduction in surface finish when the Si content of the Al—Si alloy was at least 1 wt % and a significant reduction in scratch/dig when the Si content of the Al—Si alloy was at least 5 wt %.

TABLE 2
6″ Parabolic Mirror
Base Substrate: 6061 Al

| Finishing Layer | RMS (Å) | PV (Å) | Scratch/Dig |
|---|---|---|---|
| None | 40 | >5000 | 60/40 |
| 100 wt % Al | 15 | | 60/40 |
| 99 wt % Al/1 wt % Si | <10 | | 60/40 |
| 95 wt % Al/5 wt % Si | <10 | <100 | 40/20 |
| 90 wt % Al/10 wt % Si | <10 | <80 | 20/10 |
| 80 wt % Al/20 wt % Si | <10 | <80 | 20/10 |

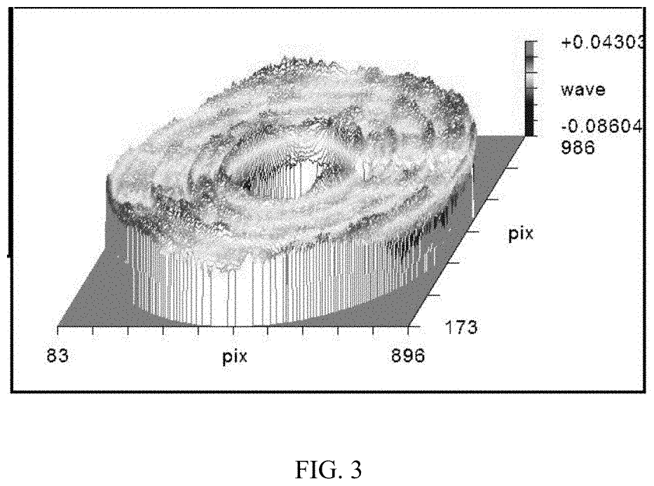

FIG. 3 shows an image obtained in a surface figure measurement from a support configured as a 6″ parabolic mirror. The support included a base substrate made from 6061 Al and a finishing layer made from an Al—Si alloy with 99 wt % Al and 1 wt % Si. After deposition, the finishing layer was diamond turned and then polished with a silica slurry. The designation “pix” refers to pixel number of the detector used for the measurement. Pixel number correlates with position on the surface. The vertical scale is color coded in gray scale and measures surface height in units of waves. Processing of the image data indicated that the surface of the finishing layer had a figure of 0.01 waves (RMS).

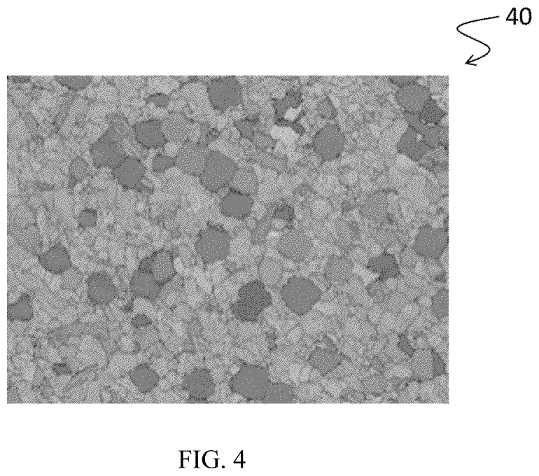

FIGS. 4-6 show Euler maps (40, 50, 60) obtained from SEM analysis of a support with a 6061 Al base substrate coated, respectively, with a finishing layer of 100 wt % Al (approximately 170 μm thick), a finishing layer of 99 wt % Al and 1 wt % Si (approximately 170 μm thick), and a finishing layer of 90 wt % Al and 10 wt % Si (approximately 75 μm thick). The SEM technique used to obtain FIGS. 4-6 utilized an EBSD (electron backscatter diffraction) detector and analysis. Each finishing layer was diamond turned and then polished with a silica slurry before completing the SEM measurements.

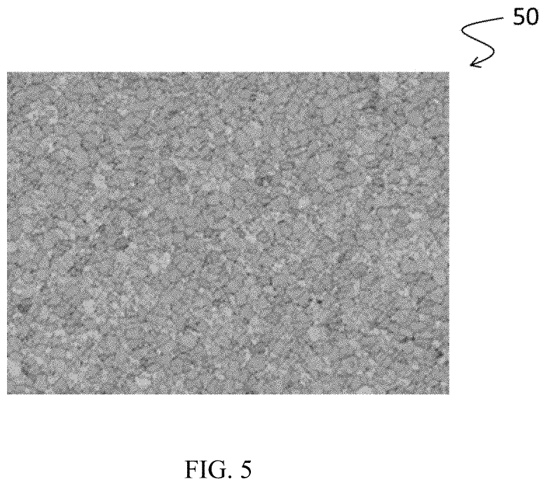

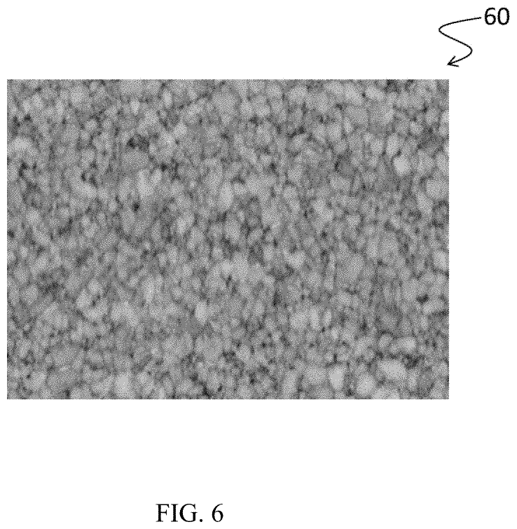

The Euler maps (40, 50, 60) shown in FIGS. 4-6 show orientations of crystalline grains in the three different finishing layers. The uniform intensity shown in the Euler maps (40, 50, 60) indicates a strong alignment of the orientation of crystalline grains. Analysis of FIG. 4 (sample size=697 grains) indicated an average grain size (equivalent diameter) of 4.1 μm and a grain size distribution ranging from 1.8 μm to 14.2 μm. The hardness and elastic modulus of the finishing layer shown in FIG. 4 were determined to be 0.5 GPa and 78.4 GPa, respectively. Analysis of FIG. 5 (sample size=1393 grains) indicated an average grain size (equivalent diameter) of 2.9 μm and a grain size distribution ranging from 1.8 μm to 7.2 μm. The hardness and elastic modulus of the finishing layer shown in FIG. 5 were determined to be 1.3 GPa and 86.2 GPa, respectively. Analysis of FIG. 6 (sample size=844 grains) indicated an average grain size (equivalent diameter) of 0.7 μm and a grain size distribution ranging from 0.36 μm to 2.1 μm. The hardness and elastic modulus of the finishing layer shown in FIG. 6 were determined to be 2.3 GPa and 95.3 GPa, respectively. The grain size analysis indicated that inclusion of Si led to a decrease in average grain size and a narrowing of the grain size distribution.

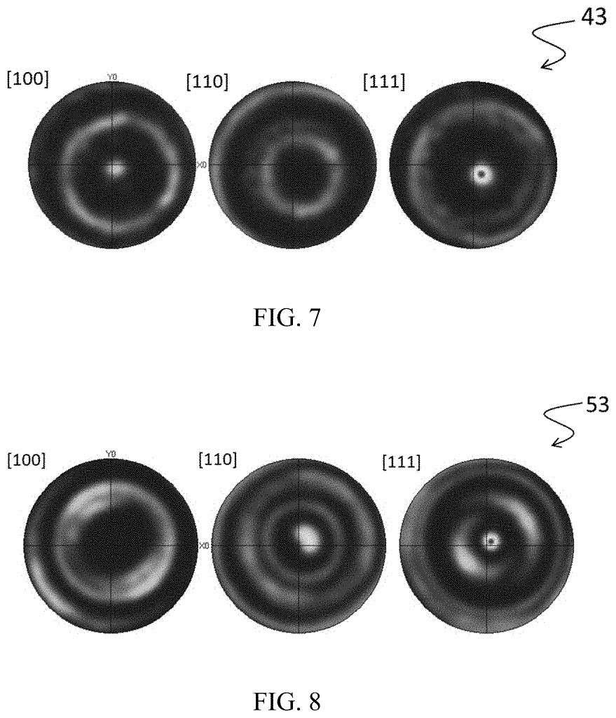

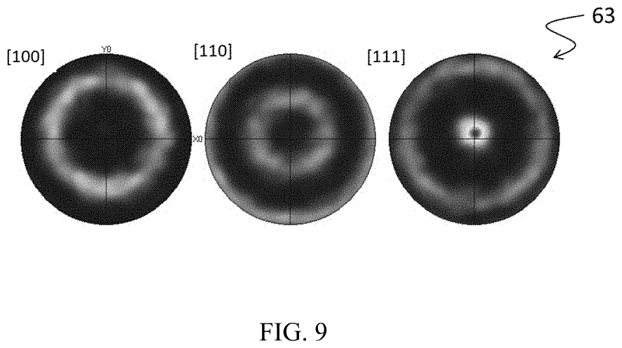

FIGS. 7-9 show pole figure maps (43, 53, 63) for the samples depicted in FIGS. 4-6, respectively. The pole figure maps (43, 53, 63) show that the orientation of the crystalline grains of each of the three different finishing layers is predominantly aligned along the [111] crystal axis. In different embodiments, the finishing layer is an Al—Si alloy in which at least 80%, or at least 85%, or at least 90%, or at least 95%, or between 80% and 99%, or between 85% and 99%, or between 90% and 99% of the grains are oriented along the [111] crystal axis.

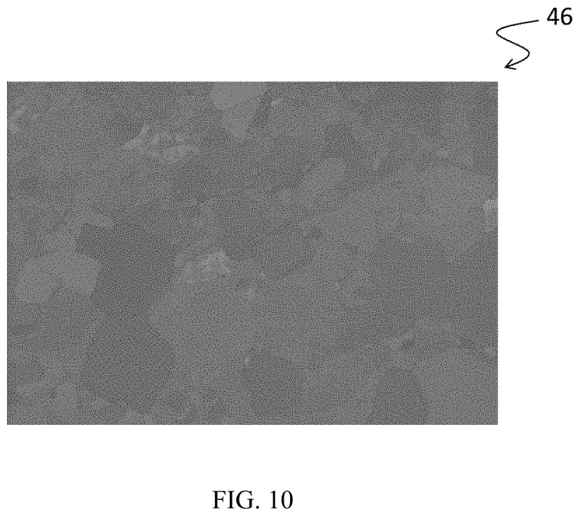

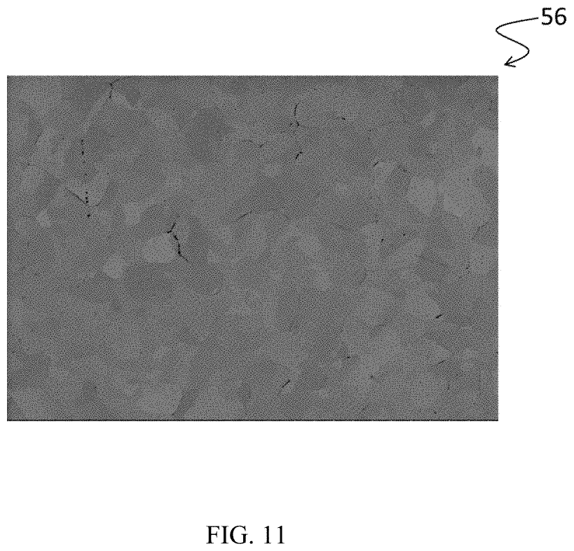

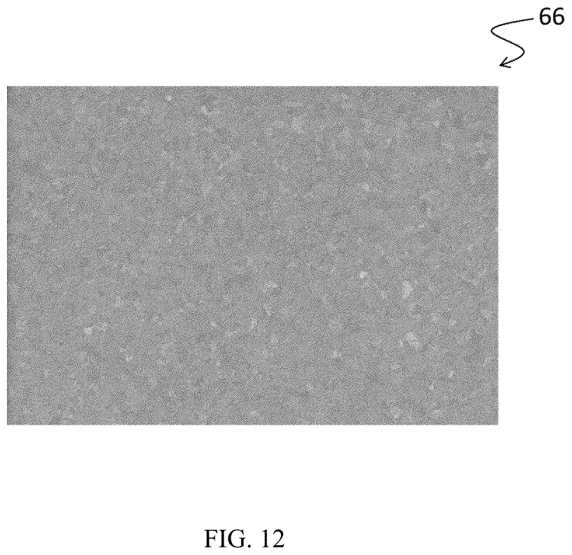

SEM images of the surfaces of the samples shown in FIGS. 4-6, respectively, are presented in FIGS. 10-12. The horizontal distance of each image shown in FIGS. 10-12 is 20 μm.

\While not wishing to be bound by theory, it is believed that the smaller and more uniformly sized grains of Al—Si alloys facilitates improvements in surface figure and finish. In some embodiments, the finishing layer is an Al—Si alloy with a grain size histogram having a maximum less than 10 μm, or less than 8 μm, or less than 6 μm, or less than 5 μm, or less than 4 μm and a full-width at half maximum less than 5 μm, or less than 4 μm, or less than 3 μm, or less than 2 μm. In some embodiments, the finishing layer is an Al—Si alloy with a grain size histogram having less than 10% of grains with a size greater than 10 μm, or less than 10% of grains with a size greater than 9 μm, or less than 10% of grains with a size greater than 8 μm, or less than 10% of grains with a size greater than 7 μm. In other embodiments, the finishing layer is an Al—Si alloy with an average grain size histogram having a maximum less than 10 μm, or less than 8 μm, or less than 6 μm, or less than 5 μm, or less than 4 μm and a full-width at half maximum less than 5 μm, or less than 4 μm, or less than 3 μm, or less than 2 μm.

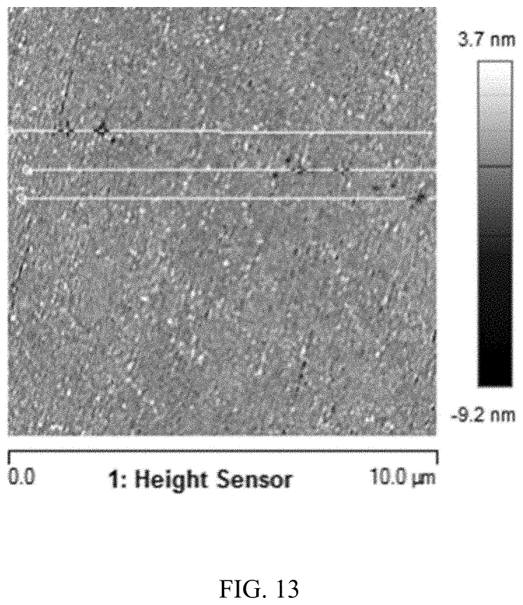

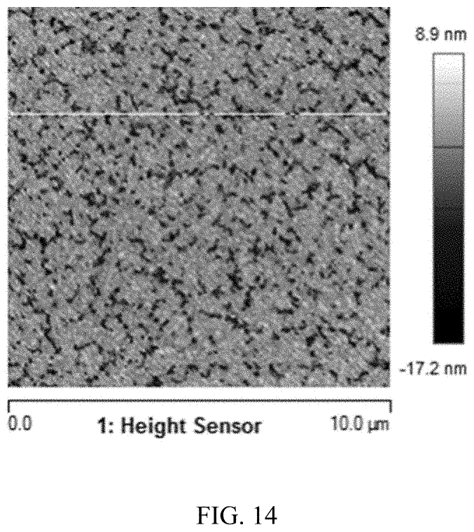

FIG. 13 shows an AFM (atomic force microscopy) image of a finishing layer containing 90 wt % Al and 10 wt % Si on a 6061 Al substrate. The height variation across selected horizontal lines of the image was determined. The height variations are shown in greyscale as indicated and provide an indication of surface irregularities such as pits. Analysis of FIG. 13 indicates that the surface is smooth with relatively few pits and has pits with small dimensions. Typical pit size is 50 nm-200 nm wide and 5 nm-12 nm deep.

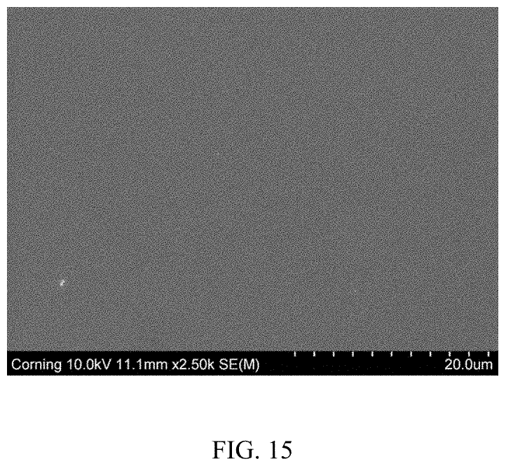

A general trend of small pit features was observed for finishing layers of binary Al—Si alloys as the Si concentration was increased up to about or slightly above 10 wt %. Further increases in Si concentration, however, led to a greater number of pits and pits with larger feature sizes. In particular, as the Si concentration was increased above about 17.5 wt %, significant interruptions of the surface of the finishing layer due to pit formation was observed. FIG. 14, for example, shows an AFM image of a finishing layer containing 80 wt % Al and 20 wt % Si. The presence and scale of pits features was greatly increased relative to a finishing layer containing 90 wt % Al and 10 wt % Si (FIG. 13). Numerous pits with widths greater than 200 nm and depths up to 35 nm were observed. While not wishing to be bound by theory, it is believed that as the Si concentration increases above about 17.5 wt %, a structural phase transformation may be occurring and promoting formation of pits and irregularities on the surface of the finishing layer.

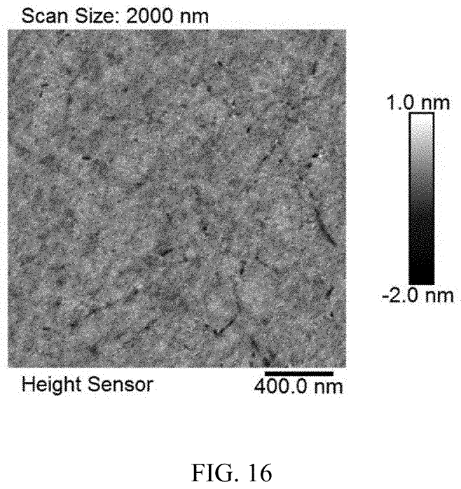

As the concentration of Si was further increased, a loss of crystallinity and a transition to an amorphous phase was observed. In particular, as the Si concentration increased above 22.5 wt %, and particularly above 35 wt %, and more particularly above 50 wt %, increasing amorphous phase character was observed. FIG. 15 shows an SEM image of a finishing layer containing 35 wt % Al and 65 wt % Si. The smooth surface texture is indicative of an amorphous material. An enlargement of a selected portion of FIG. 15 is shown in FIG. 16. Variation in surface height was limited to the order of 1 nm to a few nm. AFM images of 1″ flat samples with 6061 Al base substrates and finishing layers containing 90 wt % Al/10 wt % Si, 80 wt % Al/20 wt % Si, and 35 wt % Al/65 wt % Si were analyzed to determine the roughness parameters R_{q} and Rₐ for each finishing layer. The results are summarized in Table 3.

TABLE 3

| Finishing Layer | R_{q} (Å) | Rₐ (Å) |
|---|---|---|
| 90 wt % Al/10 wt % Si | 9.9 | 6.4 |
| 80 wt % Al/20 wt % Si | 33 | 21.2 |
| 35 wt % Al/65 wt % Si | 2.0 | 1.4 |

The smooth surface of amorphous phase finishing layers indicates that they provide an excellent surface for subsequent coating by reflective layers or reflective stack having a combination layers as described above. It is noted, however, that the CTE of amorphous phase finishing layers of binary Al—Si alloys with high Si concentration are reduced relative to binary Al—Si alloys with low Si concentration. The amorphous phase binary Al—Si alloys have a CTE too low to provide good CTE matching with Al base substrates, but are suitable for substrates (e.g. carbides and nitrides) that have lower CTE.

Aspect 1 of the description is:

1. An optical element comprising:
a base substrate, the base substrate comprising Al, an alloy of Al, Mg, or an alloy of Mg; and
a finishing layer in contact with the base substrate, the finishing layer comprising a binary alloy of Al and Si.

Aspect 2 of the description is:

The optical element of Aspect 1, wherein the base substrate has a first coefficient of thermal expansion and the finishing layer has a second coefficient of thermal expansion, the second coefficient of thermal expansion being within ±5% of the first coefficient of thermal expansion.

Aspect 3 of the description is:

The optical element of Aspect 1 or 2, wherein the base substrate comprises at least 90 wt % Al.

Aspect 4 of the description is:

The optical element of Aspect 1 or 2, wherein the base substrate comprises at least 90 wt % Mg.

Aspect 5 of the description is:

The optical element of any of Aspects 1-4, wherein the binary alloy comprises greater than 85.0 wt % Al and at least 0.5 wt % Si.

Aspect 6 of the description is:

The optical element of any of Aspects 1-4, wherein the binary alloy comprises greater than 85.0 wt % Al and at least 5.0 wt % Si.

Aspect 7 of the description is:

The optical element of any of Aspects 1-4, wherein the binary alloy comprises less than 75.0 wt % Al and greater than 25.0 wt % Si.

Aspect 8 of the description is:

The optical element of any of Aspects 1-4, wherein the binary alloy comprises less than 50.0 wt % Al and greater than 50.0 wt % Si.

Aspect 9 of the description is:

The optical element of any of Aspects 1-4, 7 or 8, wherein the binary alloy is amorphous.

Aspect 10 of the description is:

The optical element of any of Aspects 1-9, wherein the finishing layer comprises a surface with a finish less than 20 Å RMS (root-mean-square) roughness as measured by interferometry or atomic force microscopy.

Aspect 11 of the description is:

The optical element of any of Aspects 1-9, wherein the finishing layer comprises a surface with a finish less than 10 Å RMS (root-mean-square) roughness as measured by interferometry or atomic force microscopy.

Aspect 12 of the description is:

The optical element of any of Aspects 1-6 or 9-11, wherein the finishing layer includes crystalline grains.

Aspect 13 of the description is:

The optical element of Aspect 12, wherein the crystalline grains are characterized by a histogram having less than 10% of grains with a size greater than 10 μm.

Aspect 14 of the description is:

The optical element of Aspect 12 or 13, wherein at least 90% of the crystalline grains are oriented along the [111] crystal axis.

Aspect 15 of the description is:

The optical element of any of Aspects 1-14, further comprising a reflective layer in contact with the finishing layer, the reflective layer comprising a metal or a metal alloy, the metal or metal alloy comprising an element selected from the group consisting of Ag, Au, Al, Rh, Cu, Pt and Ni.

Aspect 16 of the description is:

A method of forming an optical element comprising:
forming a finishing layer on a base substrate, the finishing layer comprising a binary alloy of Al and Si, the base substrate comprising Al or Mg.

Aspect 17 of the description is:

The method of Aspect 16, wherein the base substrate comprises at least 90 wt % Al and the finishing layer comprises greater than 85 wt % Al and greater than 0.5 wt % Si.

Aspect 18 of the description is:

The method of Aspect 16 or 17, wherein the forming comprises sputtering a first target and a second target, the first target comprising Al and the second target comprising Si.

Aspect 19 of the description is:

The method of any of Aspects 16-18, further comprising processing the finishing layer, the processing comprising diamond turning the finishing layer.

Aspect 20 of the description is:

The method of any of Aspects 16-19, further comprising forming a reflective coating on the finishing layer.

Aspect 21 of the description is:

An optical element comprising:
a base substrate, the base substrate comprising Al, an alloy of Al, Mg, or an alloy of Mg; and
a finishing layer in contact with the base substrate, the finishing layer comprising an alloy of Al and Si.

Aspect 22 of the description is:

The optical element of Aspect 21, wherein the base substrate has a first coefficient of thermal expansion and the finishing layer has a second coefficient of thermal expansion, the second coefficient of thermal expansion being within ±20% of the first coefficient of thermal expansion.

Aspect 23 of the description is:

The optical element of Aspect 21 or 22, wherein the base substrate comprises at least 80 wt % Al.

Aspect 24 of the description is:

The optical element of Aspect 21 or 22, wherein the base substrate comprises at least 95 wt % Al.

Aspect 25 of the description is:

The optical element of Aspect 21 or 22, wherein the base substrate comprises at least 80 wt % Mg.

Aspect 26 of the description is:

The optical element of Aspect 21 or 22, wherein the base substrate comprises at least 95 wt % Mg.

Aspect 27 of the description is:

The optical element of any of Aspects 21-26, wherein the finishing layer comprises an alloy of Al and Si having at least 80.0 wt % Al.

Aspect 28 of the description is:

The optical element of Aspect 27, wherein the finishing layer comprises an alloy of Al and Si having at least 0.1 wt % Si.

Aspect 29 of the description is:

The optical element of Aspect 27, wherein the finishing layer comprises an alloy of Al and Si having at least 1.0 wt % Si.

Aspect 30 of the description is:

The optical element of Aspect 27, wherein the finishing layer comprises an alloy of Al and Si having at least 5.0 wt % Si.

Aspect 31 of the description is:

The optical element of Aspect 21, wherein the finishing layer comprises an alloy of Al and Si having at least 90.0 wt % Al.

Aspect 32 of the description is:

The optical element of Aspect 31, wherein the finishing layer comprises an alloy of Al and Si having at least 0.1 wt % Si.

Aspect 33 of the description is:

The optical element of Aspect 31, wherein the finishing layer comprises an alloy of Al and Si having at least 1.0 wt % Si.

Aspect 34 of the description is:

The optical element of Aspect 31, wherein the finishing layer comprises an alloy of Al and Si having at least 5.0 wt % Si.

Aspect 35 of the description is:

The optical element of Aspect 21, wherein the finishing layer comprises an alloy of Al and Si having at least 95.0 wt % Al.

Aspect 36 of the description is:

The optical element of Aspect 35, wherein the finishing layer comprises an alloy of Al and Si having at least 0.1 wt % Si.

Aspect 37 of the description is:

The optical element of Aspect 35, wherein the finishing layer comprises an alloy of Al and Si having at least 1.0 wt % Si.

Aspect 38 of the description is:

The optical element of any of Aspects 21-37, wherein the finishing layer comprises a diamond-turned surface.

Aspect 39 of the description is:

The optical element of any of Aspects 21-38, wherein the finishing layer comprises a surface with a finish less than 20 Å RMS (root-mean-square) roughness.

Aspect 40 of the description is:

The optical element of any of Aspects 21-38, wherein the finishing layer comprises a surface with a finish less than 10 Å RMS (root-mean-square) roughness.

Aspect 41 of the description is:

The optical element of any of Aspects 21-38, wherein the finishing layer comprises a surface with a finish less than 300 Å PV (peak-to-valley) roughness.

Aspect 42 of the description is:

The optical element of any of Aspects 21-38, wherein the finishing layer comprises a surface with a finish less than 100 Å PV (peak-to-valley) roughness.

Aspect 43 of the description is:

The optical element of any of Aspects 21-42, wherein the finishing layer is in direct contact with the base substrate.

Aspect 44 of the description is:

The optical element of any of Aspects 21-43, wherein the coefficient of thermal expansion of the finishing layer is within ±10% of the coefficient of thermal expansion of the base substrate.

Aspect 45 of the description is:

The optical element of any of Aspects 21-43, wherein the coefficient of thermal expansion of the finishing layer is within ±5% of the coefficient of thermal expansion of the base substrate.

Aspect 46 of the description is:

The optical element of any of Aspects 21-45, wherein the finishing layer includes crystalline grains.

Aspect 47 of the description is:

The optical element of Aspect 46, wherein the crystalline grains are characterized by a histogram having less than 10% of grains with a size greater than 10 μm.

Aspect 48 of the description is:

The optical element of Aspect 46, wherein the crystalline grains are characterized by a histogram having less than 10% of grains with a size greater than 7 μm.

Aspect 49 of the description is:

The optical element of any of Aspects 21-48, further comprising a reflective layer in contact with the finishing layer, the reflective layer comprising a metal or a metal alloy, the metal or metal alloy comprising an element selected from the group consisting of Ag, Au, Al, Rh, Cu, Pt and Ni.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

It will be apparent to those skilled in the art that various modifications and variations can be made without departing from the spirit or scope of the illustrated embodiments. Since modifications, combinations, sub-combinations and variations of the disclosed embodiments that incorporate the spirit and substance of the illustrated embodiments may occur to persons skilled in the art, the description should be construed to include everything within the scope of the appended claims and their equivalents.

What is claimed is:

1. An optical element comprising:
a base substrate, the base substrate comprising Al, an alloy of Al, Mg, or an alloy of Mg; and
a finishing layer in contact with the base substrate, the finishing layer comprising a binary alloy of Al and Si.

2. The optical element of claim 1, wherein the base substrate has a first coefficient of thermal expansion and the finishing layer has a second coefficient of thermal expansion, the second coefficient of thermal expansion being within ±5% of the first coefficient of thermal expansion.

3. The optical element of claim 1, wherein the base substrate comprises at least 90 wt % Al.

4. The optical element of claim 1, wherein the base substrate comprises at least 90 wt % Mg.

5. The optical element of claim 1, wherein the binary alloy comprises greater than 85.0 wt % Al and at least 0.5 wt % Si.

6. The optical element of claim 1, wherein the binary alloy comprises greater than 85.0 wt % Al and at least 5.0 wt % Si.

7. The optical element of claim 1, wherein the binary alloy comprises less than 75.0 wt % Al and greater than 25.0 wt % Si.

8. The optical element of claim 1, wherein the binary alloy comprises less than 50.0 wt % Al and greater than 50.0 wt % Si.

9. The optical element of claim 1, wherein the binary alloy is amorphous.

10. The optical element of claim 1, wherein the finishing layer comprises a surface with a finish less than 20 Å RMS (root-mean-square) roughness as measured by interferometry or atomic force microscopy.

11. The optical element of claim 1, wherein the finishing layer comprises a surface with a finish less than 10 Å RMS (root-mean-square) roughness as measured by interferometry or atomic force microscopy.

12. The optical element of claim 1, wherein the finishing layer includes crystalline grains.

13. The optical element of claim 12, wherein the crystalline grains are characterized by a histogram having less than 10% of grains with a size greater than 10 μm.

14. The optical element of claim 12, wherein at least 90% of the crystalline grains are oriented along the [111] crystal axis.

15. The optical element of claim 1, further comprising a reflective layer in contact with the finishing layer, the reflective layer comprising a metal or a metal alloy, the metal or metal alloy comprising an element selected from the group consisting of Ag, Au, Al, Rh, Cu, Pt and Ni.

16. A method of forming an optical element comprising:
forming a finishing layer on a base substrate, the finishing layer comprising a binary alloy of Al and Si, the base substrate comprising Al or Mg.

17. The method of claim 16, wherein the base substrate comprises at least 90 wt % Al and the finishing layer comprises greater than 85 wt % Al and greater than 0.5 wt % Si.

18. The method of claim 16, wherein the forming comprises sputtering a first target and a second target, the first target comprising Al and the second target comprising Si.

19. The method of claim 16, further comprising processing the finishing layer, the processing comprising diamond turning the finishing layer.

20. The method of claim 16, further comprising forming a reflective coating on the finishing layer.
